(19) United States
(12) Patent Application Publication
(10) Pub. No.: US 2024/0317547 A1
(43) Pub. Date: Sep. 26, 2024

(54) OVERHEAD CONVEYING VEHICLE

(71) Applicant: MURATA MACHINERY, LTD., Kyoto-shi, Kyoto (JP)

(72) Inventors: Makoto Kobayashi, Ise-shi, Mie (JP); Noritaka Kataoka, Ise-shi, Mie (JP)

(73) Assignee: MURATA MACHINERY, LTD., Kyoto-shi, Kyoto (JP)

(21) Appl. No.: 18/575,283

(22) PCT Filed: Jan. 27, 2022
(86) PCT No.: PCT/JP2022/003147

§ 371 Date: Dec. 28, 2023

(30) Foreign Application Priority Data
Jul. 5, 2021 (JP) 2021-111367

(51) Int. Cl. B66C 13/46; G05D 1/249; G05D 105/20

(52) U.S. Cl. CPC B66C 13/46; G05D 1/249; G05D 2105/20

(57) ABSTRACT

An overhead transport vehicle includes a holding unit adapted to be lifted and lowered and configured to hold an article; a lifting drive section configured to lift and lower the holding unit; a lateral transfer mechanism configured to move the lifting drive section laterally with respect to a body section; a monitoring sensor provided to the lifting drive section and configured to monitor an area below the lifting drive section and be able to change a monitoring range; and a controller configured to change the monitoring range of the monitoring sensor in accordance with information on tilt of the lifting drive section with respect to a horizontal plane.

### TECHNICAL FIELD

This disclosure relates to an overhead transport vehicle.

### BACKGROUND

As a technology related to overhead transport vehicles, a transport vehicle described in International Publication No. WO 2017/199593, for example, is known. The transport vehicle described in WO '593 includes: a body section; a lifting platform (holding unit) including a holding section configured to hold an article; a lifting drive unit (lifting drive section) configured to lift and lower the lifting platform by paying out and winding a suspending member; a swing detection sensor (monitoring sensor) provided in the lifting drive unit and configured to emit a laser beam downward and also detect the beam reflected; and a lateral feed mechanism (lateral transfer mechanism) configured to cause the lifting drive section to protrude laterally with respect to the body section to support it in a cantilevered manner.

In an overhead transport vehicle, when the lifting drive section has been moved laterally with respect to the body section by the lateral transfer mechanism (e.g., during lateral transfer), there is a possibility that a moving shaft of the lateral transfer mechanism bends, for example, thereby causing the lifting drive section to tilt with respect to the horizontal direction. If the lifting drive section tilts, the monitoring sensor may fail to correctly monitor an area below the lifting drive section due to the tilt. In this regard, the technique described above is designed to reduce the effect of the tilt of the lifting drive section by using an actuator to mechanically (physically) change the attitude of the monitoring sensor. However, there is still room for improvement in correctly monitoring the area below the lifting drive section.

It could therefore be helpful to provide an overhead transport vehicle that can correctly monitor an area below a lifting drive section even when the lifting drive section has been moved laterally.

### SUMMARY

### We Thus Provide:

An overhead transport vehicle includes: a holding unit provided to be able to be lifted and lowered and configured to hold an article; a lifting drive section configured to lift and lower the holding unit; a lateral transfer mechanism configured to move the lifting drive section laterally with respect to a body section; a monitoring sensor provided to the lifting drive section and configured to monitor an area below the lifting drive section and be able to change a monitoring range; and a controller configured to change the monitoring range of the monitoring sensor in accordance with information on tilt of the lifting drive section with respect to a horizontal plane.

Even if the lifting drive section tilts with respect to the horizontal plane (“tilt”) when the lifting drive section has been moved laterally with respect to the body section by the lateral transfer mechanism, the monitoring range of the monitoring sensor is changed by the controller in accordance with the tilt, whereby, for example, the same range as before the occurrence of the tilt can be constantly monitored. In other words, it is possible to correctly monitor the area below the lifting drive section even when the lifting drive section has been moved laterally.

The controller may store each of first to third monitoring ranges that are the monitoring range of the monitoring sensor in a manner associated with each of first to third patterns that are patterns of lifting and lowering the holding unit, and may change the monitoring range into the first monitoring range when the pattern of lifting and lowering the holding unit is the first pattern, change the monitoring range into the second monitoring range the pattern of lifting and lowering the holding unit is the second pattern, and change the monitoring range into the third monitoring range when the pattern of lifting and lowering the holding unit is the third pattern. By this configuration, when the pattern of lifting or lowering the holding unit is any one of the first to third patterns, the monitoring range of the monitoring sensor can be changed into any one of the first to third monitoring ranges in accordance with which one it is.

The first pattern may be a pattern of lifting and lowering the holding unit directly below the body section, the second pattern may be a pattern of lifting and lowering the holding unit that is not holding the article when the lifting drive section has been moved laterally with respect to the body section, and the third pattern may be a pattern of lifting and lowering the holding unit that is holding the article when the lifting drive section has been moved laterally with respect to the body section. By this configuration, the monitoring range of the monitoring sensor can be changed in accordance with each specific pattern of lifting and lowering the holding unit.

The first monitoring range may be a range oriented in a first direction along the vertical direction from the monitoring sensor in a reference attitude, the second monitoring range may be a range oriented in a second direction formed by tilting the first direction at a first angle from the monitoring sensor in the reference attitude, and the third monitoring range may be a range oriented in a third direction formed by tilting the first direction at a second angle that is larger than the first angle from the monitoring sensor in the reference attitude. Thus, the first to third monitoring ranges can be set based on knowledge that the lifting drive section is more likely to tilt when the pattern of lifting and lowering the holding unit is the second pattern than when it is the first pattern, and that the lifting drive section is more likely to tilt when the pattern of lifting and lowering the holding unit is the third pattern than when it is the second pattern.

The holding unit may be provided with a reflector, and the monitoring sensor may emit light toward the reflector and also detect return light when the light has been reflected by the reflector. Thus, the monitoring sensor can monitor an area below the lifting drive section (e.g., swinging of the holding unit) by using, for example, the presence or absence of detection of the return light.

The monitoring sensor may be able to change orientation of the monitoring range at least in a direction along a first horizontal direction. By this configuration, even if the lifting drive section tilts such that one side thereof in the first horizontal direction is lifted or lowered with respect to the other side, the orientation of the monitoring range is changed by the monitoring sensor to compensate for this tilt, whereby the area below the lifting drive section can be correctly monitored.

The first horizontal direction may correspond to a direction in which the lifting drive section is able to be moved by the lateral transfer mechanism. Thus, if a moving shaft of the lateral transfer mechanism bends when the lifting drive section has been moved laterally by the lateral transfer mechanism, the orientation of the monitoring range easily deviates in the first horizontal direction. Thus, the monitoring sensor that can change the orientation of the monitoring range in a direction along the first horizontal direction is particularly effective.

The overhead transport vehicle may include an adjustment structure configured to adjust a positional relation between the monitoring sensor and the lifting drive section such that the orientation of the monitoring range of the monitoring sensor is changed in a second horizontal direction perpendicular to the first horizontal direction. Thus, the orientation of the monitoring range of the monitoring sensor in the second horizontal direction can be adjusted by the adjustment structure.

The overhead transport vehicle may include a tilt detection sensor configured to detect the tilt of the lifting drive section with respect to the horizontal plane, and the controller may change the monitoring range of the monitoring sensor in accordance with a detection result of the tilt detection sensor. Thus, the tilt of the lifting drive section is detected by the tilt detection sensor and the monitoring range of the monitoring sensor is changed in accordance with the tilt by the controller, whereby the same range as before the occurrence of the tilt, for example, can be monitored. Thus, the area below the lifting drive section can be correctly monitored.

It is thus possible to provide the overhead transport vehicle that can correctly monitor the area below the lifting drive section even when the lifting drive section has been moved laterally.

### BRIEF DESCRIPTION OF THE DRAWINGS

FIG. 1 is a side view illustrating an overhead transport vehicle according to an example.

FIG. 2 is a front view illustrating a directly downward transfer pattern of the overhead transport vehicle in FIG. 1.

FIG. 3 is a plan view illustrating a reflector in FIG. 1.

FIG. 4(a) is a front view schematically illustrating a first monitoring range. FIG. 4(b) is a front view schematically illustrating a second monitoring range. FIG. 4(c) is a front view schematically illustrating a third monitoring range. FIG. 4(d) is a front view schematically illustrating a fourth monitoring range. FIG. 4(e) is a front view schematically illustrating a fifth monitoring range.

FIG. 5(a) is a front view illustrating a setting of the first monitoring range. FIG. 5(b) is a front view illustrating a continuation of FIG. 5(a). FIG. 5(c) is a front view illustrating a continuation of FIG. 5(b).

FIG. 6 is a front view illustrating a lateral transfer pattern for grabbing an article in the overhead transport vehicle in FIG. 1.

FIG. 7 is a front view illustrating the lateral transfer pattern for unloading the article in the overhead transport vehicle in FIG. 1.

### REFERENCE SIGNS LIST

1 overhead transport vehicle
2 frame unit (body section)
4 lateral unit (lateral transfer mechanism)
6 lifting drive unit (lifting drive section)
7 holding unit
8 transport vehicle controller (controller)
10 monitoring sensor
11 reflector
13 tilt detection sensor
200 FOUP (article)
A monitoring range
A0 first monitoring range
A11 second monitoring range
A12 third monitoring range

### DETAILED DESCRIPTION

An example will now be described in detail with reference to the drawings. In description of the drawings, like elements are designated by like reference signs, and duplicate description is omitted.

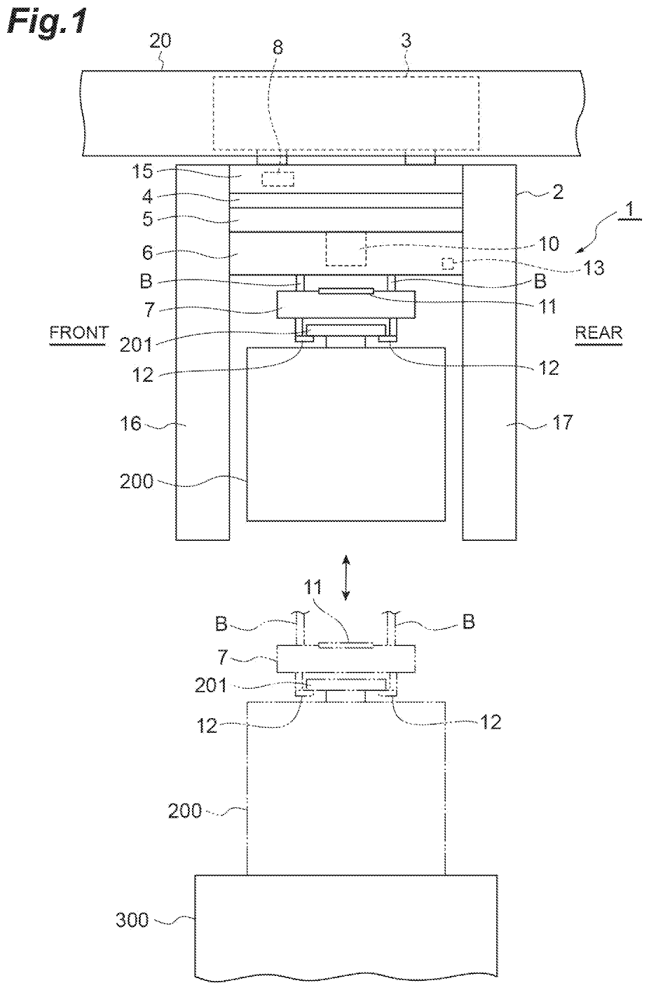

As illustrated in FIG. 1, an overhead transport vehicle 1 according to the example travels along a track 20 installed near a ceiling of a clean room in which semiconductor devices are manufactured. The track 20 forms a travel path of the overhead transport vehicle 1. The overhead transport vehicle 1 conveys a front opening unified pod (FOUP) (article) 200 housing a plurality of semiconductor wafers, and transfers the FOUP 200 to a load port 300 and the like provided on a processing device configured to perform various kinds of processing on the semiconductor wafers.

The overhead transport vehicle 1 includes a frame unit (body section) 2, a traveling unit 3, a lateral unit (lateral transfer mechanism) 4, a theta unit 5, a lifting drive unit (lifting drive section) 6, a holding unit 7, and a transport vehicle controller (controller) 8. The frame unit 2 includes a center frame 15, a front frame 16, and a rear frame 17. The front frame 16 extends downward from an end part on a front side of the center frame 15 (front side in a traveling direction of the overhead transport vehicle 1). The rear frame 17 extends downward from an end part on a rear side of the center frame 15 (rear side in the traveling direction of the overhead transport vehicle 1).

The traveling unit 3 is disposed on an upper side of the center frame 15. For example, the traveling unit 3 travels along the track 20 by receiving electric power supplied from a high-frequency current line installed along the track 20 in a non-contact manner. The lateral unit 4 is disposed on a lower side of the center frame 15. The lateral unit 4 moves the theta unit 5, the lifting drive unit 6, and the holding unit 7 laterally (sideway in the traveling direction of the overhead transport vehicle 1, in a lateral direction) with respect to the frame unit 2. The theta unit 5 is disposed on a lower side of the lateral unit 4. The theta unit 5 turns the lifting drive unit 6 and the holding unit 7 in a horizontal plane.

The lifting drive unit 6 is disposed on a lower side of the theta unit 5. The lifting drive unit 6 lifts and lowers the holding unit 7 by winding or paying out a plurality of belts (suspending members) B connected to the holding unit 7. The holding unit 7 is disposed on a lower side of the lifting drive unit 6. The holding unit 7 is provided to be able to be lifted and lowered by the lifting drive unit 6. The holding unit 7 includes a pair of grippers 12 that can open and close along a horizontal direction. The holding unit 7 holds a flange 201 of the FOUP 200 with the pair of grippers 12.

The transport vehicle controller 8 is disposed in the center frame 15. The transport vehicle controller 8 is an electronic control unit constituted of a central processing unit (CPU), a read only memory (ROM), a random access memory (RAM) and the like. The transport vehicle controller 8 controls respective parts of the overhead transport vehicle 1. The transport vehicle controller 8 may be configured with a plurality of electronic control units. The transport vehicle controller 8 may be disposed in the center frame 16, for example.

By way of example, the overhead transport vehicle 1 configured as described above operates as follows. In transferring the FOUP 200 from the load port 300 to the overhead transport vehicle 1, the overhead transport vehicle 1 not holding the FOUP 200 stops at a predetermined position above the load port 300. When the position of the holding unit 7 to be lowered in this stopping position deviates from a predetermined position with respect to the load port 300 (the FOUP 200 placed on the load port 300), the lateral unit 4 and the theta unit 5 are driven to adjust the horizontal position and the horizontal angle of the holding unit 7. Subsequently, the lifting drive unit 6 lowers the holding unit 7, and the holding unit 7 holds the flange 201 of the FOUP 200 placed on the load port 300. Subsequently, the lifting drive unit 6 lifts the holding unit 7 up to a lifting end, and disposes the FOUP 200 between the front frame 16 and the rear frame 17. Subsequently, the overhead transport vehicle 1 holding the FOUP 200 starts to travel.

In transferring the FOUP 200 from the overhead transport vehicle 1 to the load port 300, the overhead transport vehicle 1 holding the FOUP 200 stops at the predetermined position above the load port 300. When the position of the holding unit 7 (FOUP 200) to be lowered in this stopping position deviates from the predetermined position with respect to the load port 300, the lateral unit 4 and the theta unit 5 are driven to adjust the horizontal position and the horizontal angle of the holding unit. Subsequently, the lifting drive unit 6 lowers the holding unit 7, the FOUP 200 is placed on the load port 300, and the holding unit 7 releases the flange 201 of the FOUP 200. Subsequently, the lifting drive unit 6 lifts the holding unit 7 up to the lifting end. Subsequently, the overhead transport vehicle 1 not holding the FOUP 200 starts to travel.

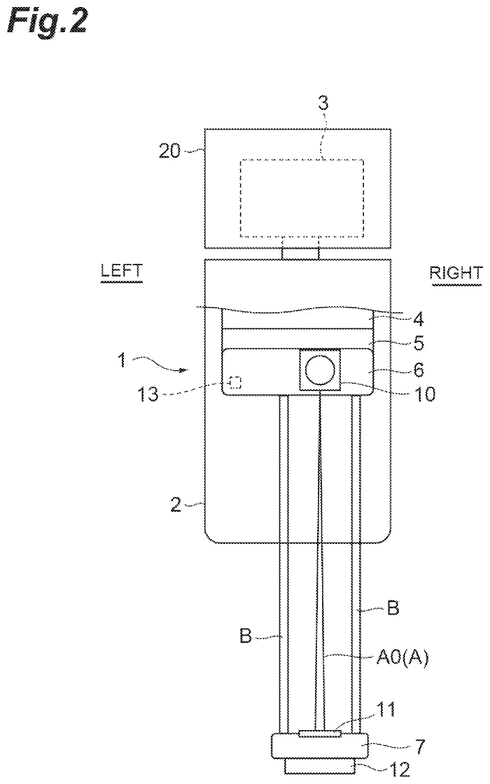

As illustrated in FIGS. 1 and 2, the overhead transport vehicle 1 includes a monitoring sensor 10, a reflector 11, and a tilt detection sensor 13. The monitoring sensor 10 is provided in the lifting drive unit 6. The monitoring sensor 10 monitors an area below the lifting drive unit 6. The monitoring sensor 10 is a sensor that can change a monitoring range (e.g., a range within which detection results are valid) A. Examples of the monitoring sensor 10 include, but is not limited to, a laser rangefinder. When the monitoring range A can be set and input, the monitoring range A is changed by changing this input. The monitoring sensor 10 emits a laser beam (light) toward the reflector 11 below and detects return light when the laser beam has been reflected by the reflector 11. The monitoring sensor 10 is connected to the transport vehicle controller 8.

The reflector 11 is provided to the holding unit 7. By way of example, the reflector 11 is provided in the center of the top of the holding unit 7. The reflector 11 is disposed with its reflective surface facing upward and reflects upward the laser beam from above. The reflector 11 is disposed directly below the monitoring sensor 10 when the lifting drive unit 6 is horizontal. The reflector 11 is not limited to a particular one, and various reflectors can be used therefor.

The tilt detection sensor 13 detects the tilt of the lifting drive unit 6 with respect to a horizontal plane. The tilt detection sensor 13 is provided in the lifting drive unit 6. Examples of the tilt detection sensor 13 may include a triaxial sensor and an acceleration sensor. When the tilt of the lifting drive unit 6 with respect to the horizontal plane is 0°, the lifting drive unit 6 is horizontal. The state in which the lifting drive unit 6 is horizontal is, for example, a state in which the longitudinal direction of the lifting drive unit 6 is in line with the horizontal plane. The state in which the lifting drive unit 6 is horizontal is, for example, a state in which a lateral direction, in which the lifting drive unit 6 is moved by the lateral unit 4, is a horizontal direction.

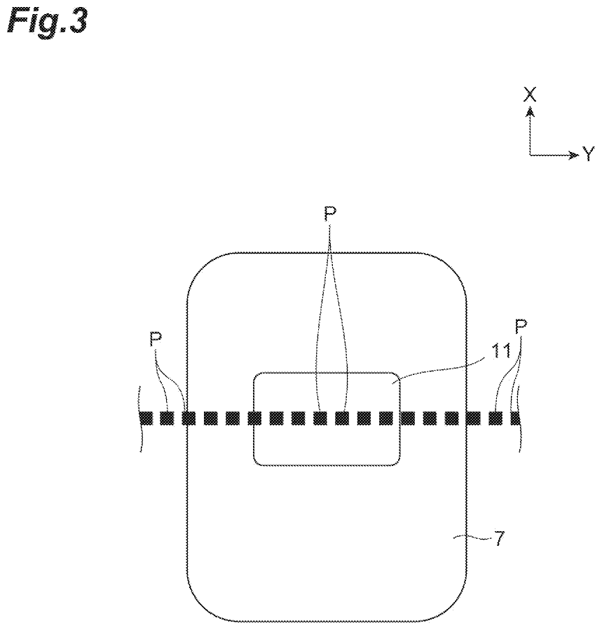

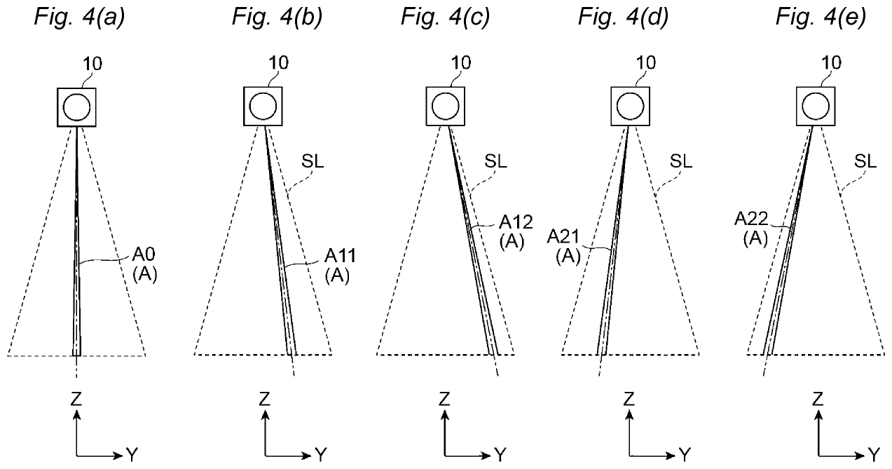

As illustrated in FIGS. 3 and 4(a), the monitoring sensor 10 performs an area scan with a laser beam L such that a light point P moves along the Y direction (first horizontal direction) that is one horizontal direction. The range SL of the area scan is a predetermined range set in advance and exists in a YZ plane when the vertical direction is defined as the Z direction. As illustrated in FIGS. 4(a) to 4(e), the monitoring sensor 10 can change the orientation of the monitoring range A in a direction along the Y direction. The Y direction in which the monitoring sensor 10 can change the orientation of the monitoring range A corresponds to a direction in which the lateral unit 4 can move the lifting drive unit 6.

The transport vehicle controller 8 changes the monitoring range A of the monitoring sensor 10 in accordance with information on the tilt of the lifting drive unit 6 with respect to the horizontal plane (“tilt information”). The transport vehicle controller 8 changes the orientation of the monitoring range A in the direction along the Y direction. The transport vehicle controller 8 here can change the monitoring range A of the monitoring sensor 10 to any of first to fifth monitoring ranges A0, A11, A12, A21, and A22. The tilt information includes information on which of first to third patterns described later the pattern of lifting and lowering the holding unit 7 is. The tilt information includes a detection result of the tilt detection sensor 13.

The first monitoring range A0 is a range oriented in a first direction along the Z direction in the monitoring sensor 10 in a reference attitude (vertical direction). The first monitoring range A0 is a reference monitoring range. The reference attitude of the monitoring sensor 10 is an attitude when the tilt of the lifting drive unit 6 with respect to the horizontal plane is 0°, the lifting drive unit 6 being provided with the monitoring sensor 10 (the same applies hereinafter). The second monitoring range A11 is a range oriented in a second direction formed by tilting the first direction at a first angle in the YZ plane in the monitoring sensor in the reference attitude. The first angle is 2° to 3°, for example.

The third monitoring range A12 is a range oriented in a third direction formed by tilting the first direction at a second angle in the YZ plane in the monitoring sensor in the reference attitude. The second angle is larger than the first angle. The second angle is 4° to 5°, for example. The fourth monitoring range A21 is a range oriented in a fourth direction formed by tilting the first direction at the first angle to the opposite side of the second monitoring range A11 in the monitoring sensor in the reference attitude. The fifth monitoring range A22 is a range oriented in a fifth direction formed by tilting the first direction at the second angle that is larger than the first angle to the opposite side of the third monitoring range A12 in the monitoring sensor in the reference attitude.

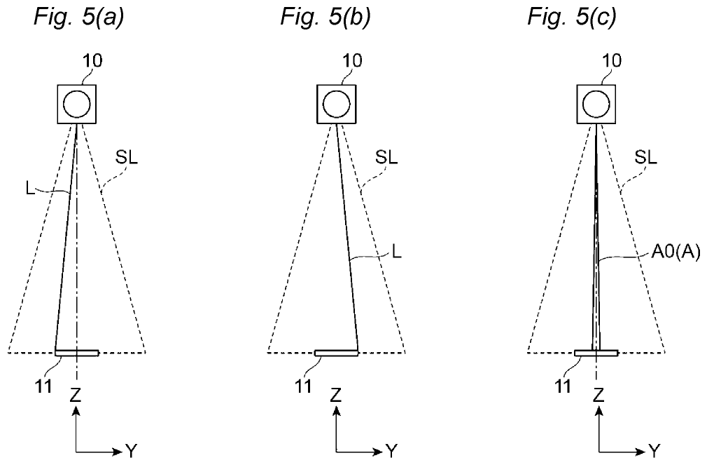

The first to fifth monitoring ranges A0, A11, A12, A21, and A22 can be set automatically by the transport vehicle controller 8, for example, as follows. Specifically, as illustrated in FIG. 5(a), an area scan with a laser beam L along the Y direction toward the reflector 11 is performed by the monitoring sensor 10 in the reference attitude. From the detection result of the monitoring sensor 10, the position of one end of the reflector 11 in the Y direction (the angle of the laser beam L capturing the one end) is determined. As illustrated in FIG. 5(b), from the detection result of the monitoring sensor 10, the position of the other end of the reflector 11 in the Y direction (the angle of the laser beam L capturing the other end) is determined.

The position of the center of the reflector 11 (the angle of the laser beam L capturing the center) is then determined based on the position of the one end and the position of the other end of the reflector 11 in the Y direction. As illustrated in FIG. 5(c), a range having a specific width with reference to the position of the center is set as the first monitoring range A0. A range formed by tilting the first monitoring range A0 at the first angle to one side in the Y direction is set as the second monitoring range A11. A range formed by tilting the first monitoring range A0 at the second angle to the one side in the Y direction is set as the third monitoring range A12. A range formed by tilting the first monitoring range A0 at the first angle to the other side in the Y direction is set as the fourth monitoring range A21. A range formed by tilting the first monitoring range A0 at the second angle to the other side in the Y direction is set as the fifth monitoring range A22. The first angle and the second angle may be predetermined, for example, by teaching in advance.

As illustrated in FIG. 1, the transport vehicle controller 8 stores each of the first to third monitoring ranges A0, A11, A12 of the monitoring sensors 10 in a manner associated with each of the first to third patterns that are patterns of lifting and lowering the holding unit 7 (also “lifting patterns”). The first pattern is a pattern of lifting and lowering the holding unit 7 directly under the center frame 15 of the frame unit 2 (see FIG. 2). The first pattern is a directly downward transfer pattern. The first pattern is a lifting pattern when the tilt of the lifting drive unit 6 is 0° or “small.”

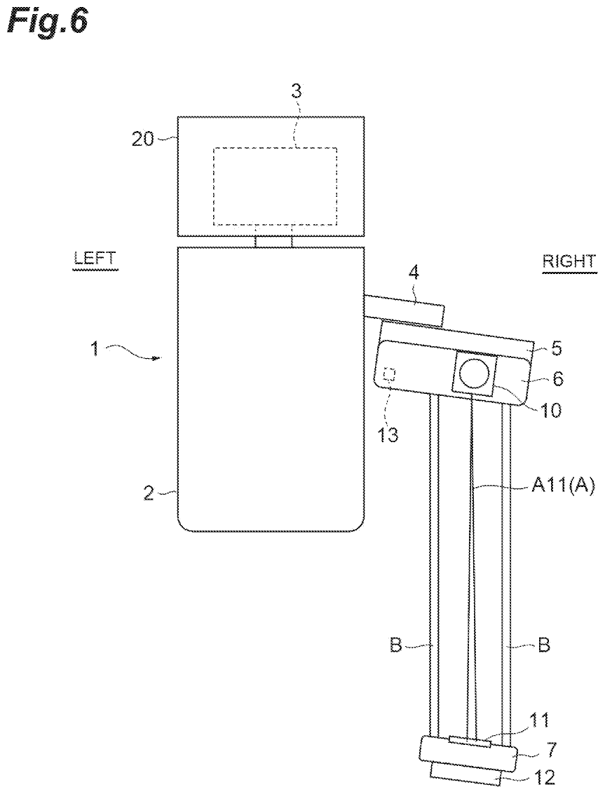

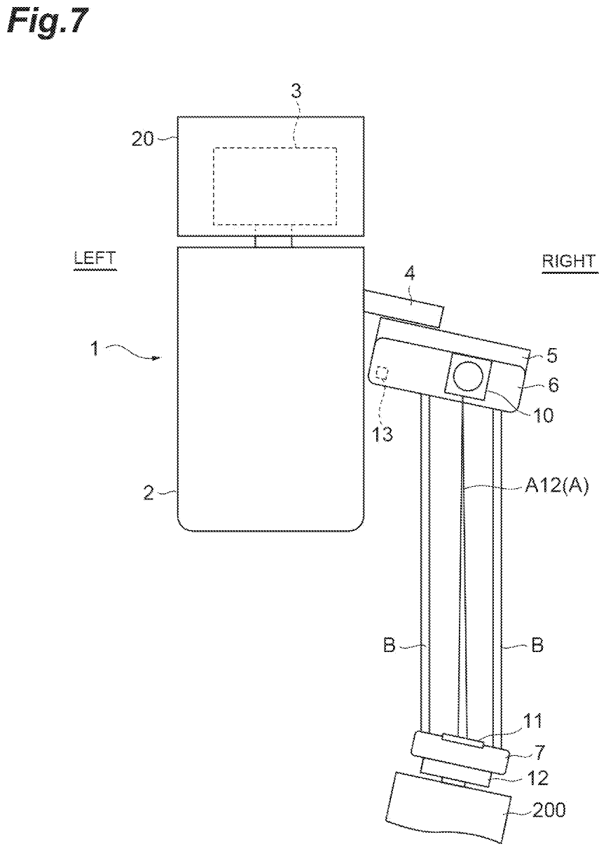

The second pattern is a pattern of lifting and lowering the holding unit 7 not holding a FOUP 200 when the lifting drive unit 6 has been moved laterally with respect to the frame unit 2 by the lateral unit 4 (see FIG. 6). The second pattern is a lateral transfer pattern for grabbing an article. The second pattern is a lifting pattern when the tilt of the lifting drive unit 6 is “medium.” The third pattern is a pattern of lifting and lowering the holding unit 7 holding a FOUP 200 when the lifting drive unit 6 has been moved laterally with respect to the frame unit 2 by the lateral unit 4 (see FIG. 7). The third pattern is a lateral transfer pattern for unloading an article. The third pattern is a lifting pattern when the tilt of the lifting drive unit 6 is “large.”

The first monitoring range A0 is a range set to face vertically downward when viewed from front when the lifting pattern is the first pattern (see FIG. 2). The second monitoring range A11 is a range set to face vertically downward when viewed from front when the lifting pattern is the second pattern (see FIG. 6). The third monitoring range A12 is a range set to face vertically downward when viewed from front when the lifting pattern is the third pattern (see FIG. 7).

When the lifting pattern is the first pattern, the transport vehicle controller 8 changes the monitoring range A into the first monitoring range A0. When the lifting pattern is the second pattern, the transport vehicle controller 8 changes the monitoring range A into the second monitoring range A11. When the lifting pattern is the third pattern, the transport vehicle controller 8 changes the monitoring range A into the third monitoring range A12. The transport vehicle controller 8 changes the monitoring range of the monitoring sensor 10 in accordance with the detection result of the tilt detection sensor 13. The lifting pattern can be determined by the transport vehicle controller 8 on the basis of, for example, driving states of various devices of the overhead transport vehicle 1, detection results of various sensors, and transport instructions received from a host controller.

The overhead transport vehicle 1 includes an adjustment structure configured to adjust a positional relation between the monitoring sensor 10 and the lifting drive unit 6 so that the orientation of the monitoring range A of the monitoring sensor 10 can be physically adjusted in the X direction (second horizontal direction) perpendicular to the Y direction. For example, the adjustment structure includes a long hole in the X direction through which a bolt is inserted to fix the monitoring sensor 10 to the lifting drive unit 6. In this example, the orientation of the monitoring range A of the monitoring sensor 10 in the X direction can be adjusted by using the long hole to adjust the position of the monitoring sensor 10 fixed to the lifting drive unit 6 in the X direction. The adjustment structure is not limited to a particular one, and various known structures may be used, or in some configurations it may be omitted. However, the physical positional relation between the monitoring sensor 10 and the lifting drive unit 6 in the Y direction is configured to be non-adjustable.

In the overhead transport vehicle 1 thus configured, for example, as illustrated in FIG. 2, if the lifting pattern is the first pattern that is the directly downward transfer pattern, the monitoring range A is set to the first monitoring range A0 by the transport vehicle controller 8, and the holding unit 7 is lifted and lowered by the lifting drive unit 6. The monitoring range A is changed by the transport vehicle controller 8 in accordance with the detection result of the tilt detection sensor 13. As a result, when the holding unit 7 is not swinging, the monitoring sensor 10 reliably receives return light from the reflector 11, and thus can detect that no swinging is occurring. When the holding unit 7 is swinging, for example, the laser beam L from the monitoring sensor 10 is not emitted onto (does not hit) the reflector 11, and the monitoring sensor 10 does not receive return light from the reflector 11. This makes it possible to detect that swinging is occurring.

In the overhead transport vehicle 1, as illustrated in FIG. 6, for example, if the lifting pattern is the second pattern that is the lateral transfer pattern for grabbing an article, the monitoring range A is set to the second monitoring range A11 by the transport vehicle controller 8, and also the holding unit 7 not holding a FOUP 200 is lifted and lowered by the lifting drive unit 6. At this time, the monitoring range A is changed by the transport vehicle controller 8 in accordance with the detection result of the tilt detection sensor 13. As a result, when the holding unit 7 is not swinging, the monitoring sensor 10 reliably receives return light from the reflector 11, and thus can detect that no swinging is occurring. When the holding unit 7 is swinging, for example, the laser beam L from the monitoring sensor 10 is not emitted onto the reflector 11, and the monitoring sensor 10 does not receive return light from the reflector 11. This makes it possible to detect that swinging is occurring.

In the overhead transport vehicle 1, as illustrated in FIG. 7, for example, if the lifting pattern is the third pattern that is the lateral transfer pattern for unloading an article, the monitoring range A is set to the third monitoring range A21 by the transport vehicle controller 8, and also the holding unit 7 holding a FOUP 200 is lifted and lowered by the lifting drive unit 6. At this time, the monitoring range A is changed by the transport vehicle controller 8 in accordance with the detection result of the tilt detection sensor 13. As a result, when the holding unit 7 is not swinging, the monitoring sensor 10 reliably receives return light from the reflector 11, and thus can detect that no swinging is occurring. When the holding unit 7 is swinging, for example, the laser beam L from the monitoring sensor 10 is not emitted onto the reflector 11, and the monitoring sensor 10 does not receive return light from the reflector 11. This makes it possible to detect that swinging is occurring.

As described above, in the overhead transport vehicle 1, even if the lifting drive unit 6 tilts when the lifting drive unit 6 has been moved laterally by the lateral unit 4, the monitoring range A of the monitoring sensor 10 can be changed by the transport vehicle controller 8 in accordance with the tilt so that, for example, the same range as before the occurrence of the tilt can be monitored. In other words, it is possible to correctly monitor the area below the lifting drive unit 6 even when the lifting drive unit 6 has been moved laterally. Even if the lifting drive unit 6 tilts during laterally downward transfer and the like, the swinging of the holding unit 7 can be detected normally.

In the overhead transport vehicle 1, the transport vehicle controller 8 stores each of the first to third monitoring ranges A0, A11, A12 in a manner associated with each of the first to third patterns of the lifting pattern. The transport vehicle controller 8 changes the monitoring range A into the first monitoring range A0 if the lifting pattern is the first pattern, changes the monitoring range A into the second monitoring range A12 when the lifting pattern is the second pattern, and changes the monitoring range A into the third monitoring range A12 when the lifting pattern is the third pattern. By this configuration, when the lifting pattern is any one of the first to third patterns, the monitoring range A can be changed into any one of the first to third monitoring ranges A0, A11, A12 in accordance with which one it is.

In the overhead transport vehicle 1, the first pattern is the directly downward transfer pattern, the second pattern is the lateral transfer pattern for grabbing an article, and the third pattern is the lateral transfer pattern for unloading an article. By this configuration, the monitoring range A of the monitoring sensor 10 can to be changed in accordance with each specific lifting pattern.

In the overhead transport vehicle 1, the first monitoring range A0 is the range oriented in the first direction along the vertical direction from the monitoring sensor 10 in the reference attitude. The second monitoring range A11 is the range oriented in the second direction formed by tilting the first direction at the first angle from the monitoring sensor 10 in the reference attitude. The third monitoring range A12 is the range oriented in the third direction formed by tilting the first direction at the second angle that is larger than the first angle from the monitoring sensor 10 in the reference attitude. In this example, the first to third monitoring ranges A0, A11, A12 can be set based on knowledge that the lifting drive unit 6 is more likely to tilt when the lifting pattern is the second pattern than when it is the first pattern, and that the lifting drive unit 6 is more likely to tilt when the lifting pattern is the third pattern than when it is the second pattern.

In the overhead transport vehicle 1, the holding unit 7 is provided with the reflector 11, and the monitoring sensor 10 emits a laser beam toward the reflector 11 and also detects return light when the laser beam L has been reflected by the reflector 11. In this example, the monitoring sensor 10 can monitor an area (e.g., swinging of the holding unit 7) below the lifting drive unit 6 by using the presence or absence of the detection of the return light.

In the overhead transport vehicle 1, the monitoring sensor 10 can change the orientation of the monitoring range A in the direction along the Y direction. By this configuration, even if the lifting drive unit 6 tilts such that one side thereof in the Y direction is lifted or lowered with respective to the other side, the orientation of the monitoring range A is changed by the monitoring sensor 10 to compensate for this tilt, whereby the area below the lifting drive unit 6 can be correctly monitored.

In the overhead transport vehicle 1, the Y direction corresponds to the direction in which the lifting drive unit 6 can be moved by the lateral unit 4. In this example, if the moving shaft of the lateral unit 4 bends when the lifting drive unit 6 has been moved laterally by the lateral unit 4, the orientation of the monitoring range A easily deviates in the Y direction. Thus, in this example, the monitoring sensor 10 that can change the orientation of the monitoring range A in the direction along the Y direction is particularly effective.

The overhead transport vehicle 1 includes the adjustment structure configured to adjust the positional relation between the monitoring sensor 10 and the lifting drive unit 6 such that the orientation of the monitoring range A of the monitoring sensor 10 is changed in the X direction. In this example, the orientation of the monitoring range A of the monitoring sensor 10 in the X direction can be adjusted by the adjustment structure.

The overhead transport vehicle 1 includes the tilt detection sensor 13 configured to detect tilt of the lifting drive unit 6, and the transport vehicle controller 8 changes the monitoring range A of the monitoring sensor 10 in accordance with a detection result of the tilt detection sensor 13. In this example, the tilt of the lifting drive unit 6 is detected by the tilt detection sensor 13 and the monitoring range of the monitoring sensor 10 is changed in accordance with the tilt by the transport vehicle controller 8, whereby the same range as before the occurrence of the tilt, for example, can be constantly monitored. Thus, the area below the lifting drive unit 6 can be correctly monitored.

The overhead transport vehicle 1 does not require a solenoid or other means to physically change the optical axis of the monitoring sensor 10 in the Y direction, and thus the structure can be prevented from becoming complicated and the number of adjustment points can be prevented from increasing. The overhead transport vehicle 1 can automatically set a plurality of the monitoring ranges A of the monitoring sensor 10.

The example has been described above, but this disclosure is not limited to the example described above. Various modifications can be made without departing from the scope of the appended claims.

In the above example, when the monitoring range A is changed in accordance with the tilt information, the monitoring range A may be changed simultaneously and in parallel with the detection of the tilt information by a sensor or the like. Instead of or in addition to this, a data table indicating a correspondence relation between a plurality of pieces of tilt information and a plurality of monitoring ranges A may be stored in a storage unit (not illustrated) by teaching in advance, for example, and the monitoring range A may be changed based on the tilt information by referring to this data table.

In the above example, the tilt information is not limited to a particular one, and may include any other information related to the tilt of the lifting drive unit 6. For example, the tilt information may further include at least one of the presence or absence of a FOUP 200 being held and the amount of movement (stroke amount) by the lateral unit 4 as tilt information on the tilt of the lifting drive unit 6. In this example, the transport vehicle controller 8 changes the monitoring range A of the monitoring sensor 10 in accordance with at least one of the presence or absence of the FOUP 200 and the amount of movement by the lateral unit 4. In this example, the monitoring ranges A can be used more properly.

In the above example, the monitoring range A is changed into any one of the first to fifth monitoring ranges A0, A11, A12, A21, and A22 of the monitoring sensor 10. However, the disclosure is not so limited. The number of monitoring ranges A to be changed is not limited to a particular one, and only needs to be two or more. The monitoring range A may be changed steplessly. In the above example, the swinging of the holding unit 7 is detected by the monitoring sensor 10. However, the monitoring sensor 10 is not limited to a particular one. For example, the monitoring sensor 10 may be what is called a look-down sensor or the like configured to emit a directional detection wave toward vicinity of a lower end, to which the holding unit 7 is to be lowered, to detect a foreign object (obstacle) at the lower end of the holding unit 7.

The materials and shapes of the respective configurations in the examples and the modifications above are not limited to those described above, and various materials and shapes can be used. Each configuration in the example or the modifications above may be optionally applied to each configuration in other examples or modifications. Some of the respective configurations in the example or the modifications above may be omitted as appropriate within the scope not departing from the appended claims.

1.-9. (canceled)

10. An overhead transport vehicle comprising:
a holding unit adapted to be lifted and lowered and configured to hold an article;
a lifting drive section configured to lift and lower the holding unit;
a lateral transfer mechanism configured to move the lifting drive section laterally with respect to a body section;
a monitoring sensor provided to the lifting drive section and configured to monitor an area below the lifting drive section and be able to change a monitoring range; and
a controller configured to change the monitoring range of the monitoring sensor in accordance with information on tilt of the lifting drive section with respect to a horizontal plane, wherein
the monitoring sensor is a sensor configured to perform an area scan of a laser beam such that a light point moves along a first horizontal direction corresponding to a direction in which the lifting drive section is able to be moved by the lateral transfer mechanism, and changes the monitoring range included in a range of the area scan by changing set input.

11. The overhead transport vehicle according to claim 10, wherein
the controller stores each of first to third monitoring ranges that are the monitoring range of the monitoring sensor in a manner associated with each of first to third patterns that are patterns of lifting and lowering the holding unit, and
changes the monitoring range into the first monitoring range when the pattern of lifting and lowering the holding unit is the first pattern, changes the monitoring range into the second monitoring range when the pattern of lifting and lowering the holding unit is the second pattern, and changes the monitoring range into the third monitoring range when the pattern of lifting and lowering the holding unit is the third pattern.

12. The overhead transport vehicle according to claim 11, wherein
the first pattern is a pattern of lifting and lowering the holding unit directly below the body section,
the second pattern is a pattern of lifting and lowering the holding unit that is not holding the article when the lifting drive section has been moved laterally with respect to the body section, and
the third pattern is a pattern of lifting and lowering the holding unit that is holding the article when the lifting drive section has been moved laterally with respect to the body section.

13. The overhead transport vehicle according to claim 12, wherein
the first monitoring range is a range oriented in a first direction along a vertical direction in the monitoring sensor in a reference attitude,
the second monitoring range is a range oriented in a second direction formed by tilting the first direction at a first angle in the monitoring sensor in the reference attitude, and
the third monitoring range is a range oriented in a third direction formed by tilting the first direction at a second angle that is larger than the first angle in the monitoring sensor in the reference attitude.

14. The overhead transport vehicle according to claim 10, wherein
the holding unit is provided with a reflector, and
the monitoring sensor emits light toward the reflector and also detects return light when the light has been reflected by the reflector.

15. The overhead transport vehicle according to claim 10, wherein the monitoring sensor is able to change orientation of the monitoring range in a direction along a first horizontal direction.

16. The overhead transport vehicle according to claim 15, wherein the first horizontal direction corresponds to a direction in which the lifting drive section is able to be moved by the lateral transfer mechanism.

17. The overhead transport vehicle according to claim 15, comprising an adjustment structure configured to adjust a positional relation between the monitoring sensor and the lifting drive section such that the orientation of the monitoring range of the monitoring sensor is changed in a second horizontal direction perpendicular to the first horizontal direction.

18. The overhead transport vehicle according to claim 10, comprising a tilt detection sensor configured to detect the tilt of the lifting drive section with respect to the horizontal plane, wherein
the controller changes the monitoring range of the monitoring sensor in accordance with a detection result of the tilt detection sensor.
